(19) United States
(12) Patent Application Publication
(10) Pub. No.: US 2025/0231229 A1
(43) Pub. Date: Jul. 17, 2025

(54) Power Quality Measurement for a Grid-Connected Generator System

(71) Applicant: Caterpillar Energy Solutions GmbH, Mannheim (DE)

(72) Inventor: Assiet AREN, Mannheim (DE)

(73) Assignee: Caterpillar Energy Solutions GmbH, Mannheim (DE)

(21) Appl. No.: 19/022,092

(22) Filed: Jan. 15, 2025

(30) Foreign Application Priority Data
Jan. 17, 2024 (DE) 10 2024 101 253.6

(51) Int. Cl. G01R 27/26

(52) U.S. Cl. CPC G01R 27/2688

(57) ABSTRACT

The present invention relates to a method for checking the power quality of a generator system, particularly a grid-connected generator system, as well as to a corresponding device. Accordingly, a method for checking the power quality of a generator system is proposed, wherein the connection of the generator system is electrically conductively connected to a consumer's connection, wherein an impedance is provided between the connections, and it is determined, based on an impedance value measured during the generator system operation, whether the generator system provides a specified power output.

### TECHNICAL FIELD

The present invention relates to a method for checking the power quality of a generator system, particularly a grid-connected generator system, as well as to a corresponding device.

### PRIOR ART

For consumers such as a power grid, certification standards for generator systems may require the verification or confirmation of compatibility between the generator system and the grid. To ensure sufficient power quality, generator systems must remain balanced in the absence of opposing consumer voltage, i.e., when the opposing voltage is zero. In other words, the current values in each of the three phases must essentially be equal to prevent unbalanced or asymmetrical currents from being fed into the grid. This requirement applies even if the consumer or its connection is itself unbalanced or asymmetrical.

The consumer can influence the current values measured at the generator system's connection, which may complicate verifying compatibility between the generator system and the consumer. For generator systems designed as synchronous machines that feed power directly into the grid without a grid-side converter, an individual phase adjustment is not readily feasible. Moreover, adapting the generator system's connection to create an electrically conductive link with the consumer in line with new safety standards entails significant costs.

Thus, there is a need for a reliable method to verify compatibility between generator systems and consumers with existing connections, particularly without requiring extensive modifications to the connection.

### DISCLOSURE OF THE INVENTION

Based on the known prior art, the objective of the present invention is to provide an improved method for checking the power quality of a generator system and a corresponding device.

This objective is achieved through a method with the features outlined in claim 1. Advantageous further developments are detailed in the dependent claims, the description, and the figures.

Accordingly, a method for checking the power quality of a generator system is proposed, wherein the connection of the generator system is electrically conductively connected to a consumer's connection, wherein an impedance is provided between the connections, and it is determined, based on an impedance value measured during the generator system operation, whether the generator system provides a specified power output.

The additional impedance substantially mitigates local influences at the connection, enabling a valid verification of the generator system's power quality. The actual impedance value also indicates the generator system's performance, allowing the power quality to be assessed advantageously considering the impedance value. Adding the impedance is relatively cost-effective, offering a simple and economical solution for verifying the generator system's compatibility. For example, the impedance may be implemented in a test device for verifying “Fault Ride Through” (FRT), i.e., checking the ability of the generator system to ride through low-voltage conditions and/or faults.

Preferably, the specified power output is indicative of whether electrical symmetry or asymmetry is present. Specifically, the method may involve determining a ratio between the negative-sequence current and the positive-sequence current of the generator system, based on the measured impedance value, wherein the ratio indicates the specified power output. This ratio may particularly indicate a symmetry or asymmetry, enabling verification of whether the generator system ensures sufficient symmetry in the supplied current based on the ratio.

It was recognized that the positive sequence current value (I(System)_{Mit}) and the negative sequence current value (I(System)_{Geg}) can be determined for the generator system using the following equations:

$${I ( System )}_{Mit} = \frac{( {V ( System )}_{Mit} - {V ( Consumer )}_{Mit} )}{{{Z ( Consumer )}_{}}_{Mit} + Z {1}_{Mit}} \qquad ( 1 )$$

$${I ( System )}_{Geg} = \frac{( {V ( System )}_{Geg} - {V ( Consumer )}_{Geg} )}{{{Z ( Consumer )}_{}}_{Geg} + Z {1}_{Geg}} \qquad ( 2 )$$

wherein the voltage V for the generator system and for the load or a network is taken into account for both the positive system (Mit) and negative system (Geg). Furthermore, the impedance Z for the load and the added at least one impedance Z1 for the positive-sequence system and the negative-sequence system are also taken into account.

This results in the following ratio:

$$Ratio = \frac{{I ( System )}_{Geg}}{{I ( System )}_{Mit}} = \frac{- {V ( Consumer )}_{Geg}}{( {Z ( Consumer )}_{Geg} + Z {1}_{Mit} ) * {I ( System )}_{Mit}} \qquad ( 3 )$$

A specified power output is determined if the ratio is below a predefined threshold value, wherein the threshold value is preferably between 1 percent and 10 percent, particularly below 5 percent. The negative-sequence current is preferably much smaller than the positive-sequence current, meaning the ratio corresponds to high power quality at the specified output. To ensure particularly high power quality and compatibility with the consumer, a threshold value below 5 percent can be chosen, such as below 2 percent or even below 1.5 percent.

Experiments have shown that V(System)_{Geg} is equal to a zero value, wherein V(Consumer)_{Geg} and Z(Consumer)_{Geg} have proven to be essentially constants due to the considerably higher short-circuit power of the consumer compared to the short-circuit power of the generator system. Similarly, it can be assumed that I(System)_{Mit} remains essentially constant even with the added impedance, especially since the generator system is usually set up to generate or provide a constant power.

Accordingly, determining the specified power output can be achieved by comparing the measured impedance value with a predefined threshold value. Specifically, determining the specified power output may be based solely on comparing the measured impedance value to the threshold value, preferably considering the positive-sequence impedance. As indicated by the above equation (3) and the corresponding assumptions, the ratio can be determined predominantly as a function of the impedance value, whereby the ratio is reduced when the impedance value increases. The impedance value may depend on the generator system's power output or the grid's short-circuit power, wherein the threshold values can range from 1 ohm to 60 ohms or higher. For example, the threshold value could lie between 5 ohms and 25 ohms, or between 10 ohms and 20 ohms, or exceed 60 ohms.

Advantageously, one or more threshold values for the impedance can be established based on known constants, each corresponding to a specific ratio. If such a threshold value is not reached, the impedance value indicates a ratio corresponding to an unacceptable asymmetry in the supplied current, meaning the generator system cannot meet the specified power output. Conversely, exceeding the threshold value corresponds to sufficient symmetry in the supplied current, indicating that the specified power output is achieved. In this way, the impedance value can be used to verify or confirm the compatibility of the generator system with the consumer.

A signal may be generated to indicate whether the generator system provides the specified power output, with the signal preferably including a switching signal for the generator system. In this way, the corresponding result can be communicated to technical personnel, for example, and the result can also be saved based on the signal. If no specified power output is detected and an unacceptable asymmetry is present, an error message and/or warning signal can be generated. Optionally, the generator system may be fully disconnected from the consumer using the switching signal. Similarly, a signal confirming the generator system's compatibility may be generated, optionally including a switching signal to keep the generator system connected to the consumer or to enable this connection.

While the generator system may be connected to various consumers, such as industrial consumers or local installations, the consumer is preferably a grid. The network may also include an asymmetrical connection or have asymmetries in the requested load, for example due to consumer fluctuations or irregularities in the network. The present invention advantageously enables the generator system to be validly verified for power quality even when connected to such a grid.

The generator system can continue providing a three-phase power. Specifically, the generator system may be a synchronous machine without a grid-side converter. Unlike wind turbines or photovoltaic systems, the generated power can preferably be fed directly into the grid without adjusting individual phases. In this configuration, the positive-sequence and negative-sequence components correspond to the respective line currents or phasors.

The intended respective impedance or respective multiple impedances and/or the phasors is/are preferably the same for each phase and it can be determined for each individual phase whether a predetermined power is provided by the generator system. A phase-specific signal can be generated based on the result for each phase. Although the procedure does not provide for an immediate adjustment of the phases, it can still be used to demonstrate whether a specific problem exists for one or more phases, thus facilitating troubleshooting.

To facilitate and control the method, one or more additional switches, preferably in the form of circuit breakers, can be provided. These switches can, for example, simplify creating an electrically conductive connection between the generator system and the consumer and/or allow selective execution of the method. Preferably, a direct electrically conductive connection between the generator system's connection and the consumer's connection is provided via a switch parallel to the impedance, before and/or after the impedance measurement. Such a switch or circuit breaker enables bypassing the impedance, allowing the generated current to flow directly to the consumer. For example, the switch can be actuated based on an output signal when the generator system achieves the specified power output. Conversely, a direct connection can be avoided using the switch if the measured impedance value is too low and does not exceed the predefined threshold.

Alternatively or additionally, it may also be possible that no electrically conductive connection is provided between the generator system's connection and the consumer's connection before and/or after the impedance measurement via a switch located in series with the impedance and the consumer's connection. In other words, a series switch (e.g., a circuit breaker) may be provided before the impedance, which is only activated when the method is executed. For example, both a parallel circuit breaker and a series circuit breaker may be initially opened, after which the series circuit breaker is closed to perform the procedure.

If it is determined that the generator system provides the specified power output, the parallel circuit breaker can be closed to allow direct feeding into the grid. If the generator system does not provide the specified power output, both the series circuit breaker and the parallel circuit breaker can be opened to completely disconnect the generator system from the grid. Providing both circuit breakers (the series circuit breaker and the parallel circuit breaker) enables selective switching while also simplifying the connection between the consumer and the generator system.

The objective is further achieved by a device for checking the power quality of a generator system, as described in claim 13. Advantageous further developments of the method are detailed in the dependent claims, the description, and the figures.

Accordingly, a device for checking the power quality of a generator system is proposed, comprising an interface for electrically connecting the device to the generator system's connection and an interface for electrically connecting the device to a consumer as well as at least one impedance which is arranged between the interfaces in such a way that a current is conducted from the generator system to the consumer via the at least one impedance when the interfaces are connected and when the generator system is in operation. An evaluation unit is connected to the impedance and designed to determine whether the generator system provides the specified power output based on the measured impedance value and to output a corresponding signal. The impedance value may optionally be measured or recorded using an impedance measurement device integrated into or connected to the evaluation unit.

The device can be implemented in a test device for verifying “Fault Ride Through” (FRT), i.e., which checks the generator system's ability to ride through low voltage or fault conditions. Multiple impedances may be arranged in series to form a combined impedance, or individual impedances may be provided for each phase of the generator system, which supplies a three-phase current, wherein preferably, these impedances are equal.

The device is preferably designed to execute the method described above, meaning that aspects, features, and advantages described for the method also apply to the device, avoiding redundant explanations.

As outlined for the method, the device may also include one or more switches or circuit breakers. A switch parallel to the impedance can be provided to create a direct electrically conductive connection between the connection of the generator system and the connection of the consumer. Alternatively or additionally, a switch may be positioned between the consumer-side interface and the impedance or in series with the impedance. These switches can, for example, simplify creating an electrically conductive connection between the generator system and the consumer and/or allow selective execution of the method. They also enable disconnection of the generator system from the consumer or grid or allow direct feeding of generated power into the grid.

### BRIEF DESCRIPTION OF THE FIGURES

Preferred embodiments of the invention are further explained using the following FIGURE:

FIG. 1: a schematic representation of a device according to the invention for executing the method in a preferred embodiment.

### DETAILED DESCRIPTION OF PREFERRED EMBODIMENTS

Preferred embodiments are described below with reference to the FIGURE.

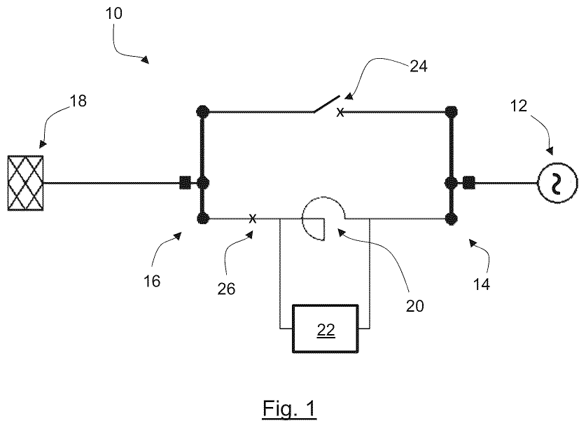

FIG. 1 schematically shows a device 10 for checking the power quality of a generator system 12. To establish an electrically conductive connection between the device 10 and the generator system 12, an interface 14 is provided, which can be connected to a connection or terminal of the generator system 12. Similarly, an interface 16 is provided to create an electrically conductive connection for connecting a consumer 18. In the present example, the generator system 12 is a synchronous machine designed to provide a three-phase current, wherein the consumer 18 is a grid.

To verify whether the generator system 12 provides sufficient power quality, an impedance 20 is placed between the interfaces 14, 16. As described earlier, the impedance 20 can be used to verify whether a specified ratio between the negative-sequence current and the positive-sequence current is achieved, excluding unacceptable asymmetries in the generator system 12. For example, a threshold value for the impedance 20 can be set, which corresponds to a predetermined ratio and should be exceeded in the case of a predetermined power or sufficient power quality. In order to enable this comparison, an evaluation unit 22 is provided which receives the measured impedance values and can advantageously be designed to compare the measured impedance value with a specified threshold value and to output a signal corresponding to the result.

To enable selective impedance measurement, two switches 24, 26 are included as circuit breakers. The switch 24, arranged parallel to the impedance 20, allows a direct electrically conductive connection between interfaces 14, 16, i.e., between the generator system 12 and the consumer 18. The switch 24 can also disconnect the direct connection if the generator system 12 needs to be isolated from the consumer 18.

The switch 26 is arranged in series with the impedance 20 and between the impedance 20 and interface 16. By operating the switch 26, the power quality can be checked selectively by passing the current generated by the generator system 12 through the impedance 20 only when the switch 24 is open and when the switch 26 is closed. In this case, the evaluation unit 22 determines the corresponding impedance value, which is characteristic of the performance and power quality of the generator system 12.

Although not shown in the schematic representation of FIG. 1, additional components may be provided between the generator system 12 and the consumer 18. Specifically, one or more transformers may be included on the generator system 12 side, connected via appropriate terminals or connectors, preferably in series. The switches 24, 26 are optional and may be included depending on the required configuration.

Where applicable, all individual features illustrated in the embodiments can be combined and/or exchanged without departing from the scope of the invention.

1. A method for checking the power quality of a generator system, wherein a connection of the generator system is electrically conductively connected to a connection of a consumer, wherein an impedance is provided between the connections, and wherein it is determined, based on an impedance value measured during the operation of the generator system, whether the generator system provides a specified power output.

2. The method according to claim 1, wherein the specified power output is indicative of the presence of electrical symmetry or asymmetry.

3. The method according to claim 1, wherein a ratio between the negative-sequence current and the positive-sequence current of the generator system is determined based on the measured impedance value, and the ratio indicates the specified power output.

4. The method according to claim 3, wherein the specified power output is determined if the ratio is below a predefined threshold value, wherein the threshold value is preferably between 1 percent and 10 percent, particularly less than 5 percent.

5. The method according to claim 1, wherein determining the specified power output is based on comparing the measured impedance value to a predefined threshold value.

6. The method according to claim 5, wherein determining the specified power output is based solely on comparing the measured impedance value to the predefined threshold value, preferably considering the impedance value for the positive-sequence current.

7. The method according to claim 1, wherein a signal is generated to indicate whether the generator system provides the specified power output, wherein the signal preferably includes a switching signal for the generator system.

8. The method according to claim 1, wherein the generator system provides a three-phase current.

9. The method according to claim 8, wherein the generator system is a synchronous machine free of a connection-side converter.

10. The method according to claim 8, wherein the impedance is the same for each phase, and it is determined for each individual phase whether the generator system provides the specified power output, wherein a phase-specific signal is preferably output based on the result.

11. The method according to claim 1, wherein the consumer is a grid, preferably with an asymmetrical connection.

12. The method according to claim 1, wherein:
a direct electrically conductive connection between the generator system's connection and the consumer's connection is provided via a switch parallel to the impedance, before and/or after the impedance measurement; and/or
no electrically conductive connection is provided between the generator system's connection and the consumer's connection via a switch between the impedance and the consumer's connection, before and/or after the impedance measurement.

13. A device for checking the power quality of a generator system, comprising:
an interface for electrically connecting the device to a connection of the generator system and an interface for electrically connecting the device to a consumer;
at least one impedance arranged between the interfaces such that current flows from the generator system to the consumer through the impedance when the interfaces are connected and the generator system is operating; and
an evaluation unit connected to the impedance and designed to determine whether the generator system provides the specified power output based on the measured impedance value and to output a corresponding signal.

14. The device according to claim 13, which is configured to execute the method according to claim 1.

15. The device according to claim 13, comprising:
a switch arranged parallel to the impedance and designed to provide a direct electrically conductive connection between the generator system's connection and the consumer's connection; and/or
a switch arranged between the consumer-side interface and the impedance.
